(19) United States
(12) Patent Application Publication
(10) Pub. No.: US 2026/0319360 A1
(43) Pub. Date: Oct. 15, 2026

(54) PHOTORESIST COMPOSITION

(71) Applicants: TAIWAN SEMICONDUCTOR MANUFACTURING COMPANY, LTD., Hsinchu (TW); NATIONAL TSING HUA UNIVERSITY, Hsinchu City (TW)

(72) Inventors: Jui-Hsiung LIU, Taipei City (TW); Burn Jeng LIN, Hsinchu City (TW); Yu-Fang TSENG, New Taipei City (TW); Jia-Rong WU, Yunlin County (TW); Po-Hsiung CHEN, Taichung City (TW); Tsai-Sheng GAU, Hsinchu City (TW)

(73) Assignees: TAIWAN SEMICONDUCTOR MANUFACTURING COMPANY, LTD., Hsinchu (TW); NATIONAL TSING HUA UNIVERSITY, Hsinchu City (TW)

(21) Appl. No.: 19/178,432

(22) Filed: Apr. 14, 2025

(51) Int. Cl. G03F 7/004; G03F 7/00; G03F 7/20; H10P 50/00; H10P 76/20

(52) U.S. Cl. CPC G03F 7/0042; G03F 7/2004; G03F 7/70033; G03F 7/702; G03F 7/70233; H10P 76/204; H10P 50/69; H10P 50/71; H10P 50/73

(57) ABSTRACT

In some embodiments, a photoresist composition comprises a first metallic photoresist and a second metallic photoresist. The first metallic photoresist has a formula (1): [(RSn)₁₂O₁₄(OH)₆](X)₂ (1), wherein in the formula (1), R is alkyl or alkenyl, and X is BF₄, OTf or SbF₆. The second metallic photoresist has a composition different from the formula (1) of the first metallic photoresist.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, patterns are formed on the semiconductor wafer which incorporates minimum feature sizes under a resolution or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic view of an Extreme ultraviolet lithography (EUVL) tool with an LPP-based EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIG. 1C is a sectional view of a EUV mask constructed in accordance with some embodiments of the present disclosure.

FIGS. 2-3 and 5-7 illustrate fragmentary cross-sectional side views of a semiconductor device in accordance with various aspects of the present disclosure.

FIGS. 4A-4B show a mechanism of the ejection of an electron of the photoresist layer upon absorbing the EUV radiation in accordance with some embodiments.

FIGS. 8-10 illustrate fragmentary cross-sectional side views of a semiconductor device in accordance with various aspects of the present disclosure.

FIG. 11 illustrates an example of a FinFET in a three-dimensional view, in accordance with some embodiments.

FIGS. 12A, 12B, 12C, 12D and 13-23C are cross-sectional views of intermediate stages in the manufacturing of FinFETs, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Inorganic photoresists can be used as next-generation extreme ultraviolet (EUV) radiation photoresists due to strong absorption ability and small etching rates in the resistance test. 12-Tin-oxo clusters have high threshold energy up to about 1100±10 μC/cm² as determined by e-beam contrast curve. Although the 12-Tin-oxo clusters can achieve EUV resolutions with small half-pitch (HP) of about 13 nm to about 14 nm, the EUV exposure energy dose required may exceed 200 mJ/cm², which is much higher than those expected for integrated circuits, which may be lower than 60 mJ/cm².

Some embodiments of the present disclosure provide an inorganic photoresist composition with high EUV resolution patterns (such as about 13 nm to about 16 nm) which can be obtained using low energy dose. For example, the EUV resolution can be improved to be pattern with a HP of about 13 nm to about 14 nm, and the EUV energy dose required is less than about 70 mJ/cm². The inorganic photoresist composition can also increase the metal content to improve the etching rates in the resistance test. For example, the first metallic photoresist can have high inorganic SnO₂/X content (e.g., X can be BF₄ or SbF₆) of about 60% to 70% with good air stability.

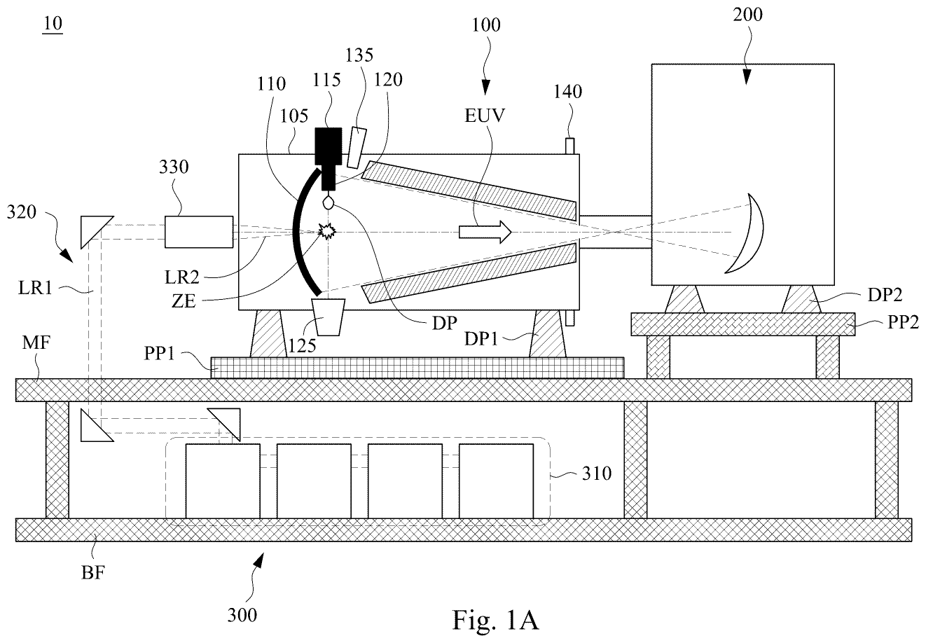

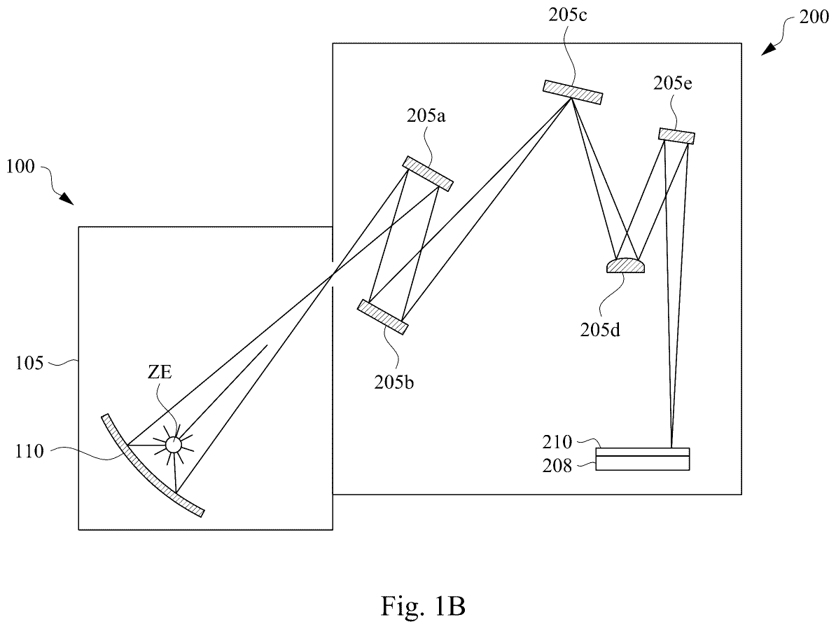

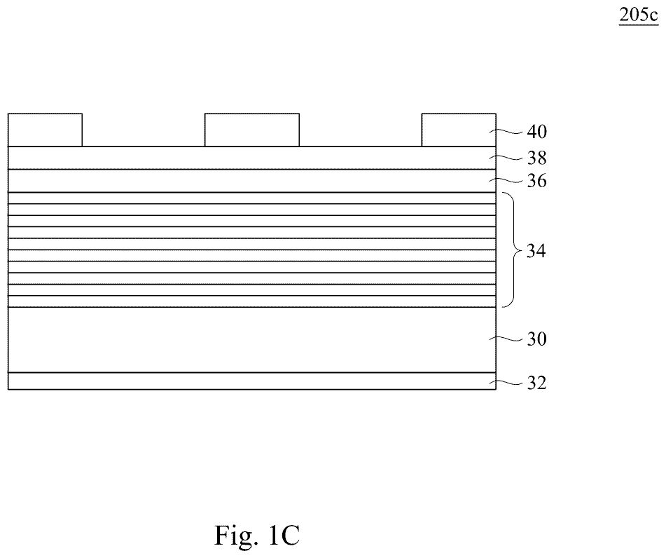

FIG. 1A is a schematic view diagram of an EUV lithography system 10, constructed in accordance with some embodiments. The EUV lithography system 10 may also be generically referred to as a scanner that is configured to perform lithography exposure processes with respective radiation source and exposure mode. The EUV lithography system 10 is designed to expose a photoresist layer by an EUV light or EUV radiation. The photoresist layer is a material sensitive to the EUV light. The EUV lithography system 10 employs a radiation source 100 to generate EUV light, such as EUV light having a wavelength ranging between about 1 nm and about 100 nm. In one particular example, the radiation source 100 generates an EUV light with a wavelength centered at about 13.5 nm. Accordingly, the radiation source 100 is also referred to as EUV radiation source 100.

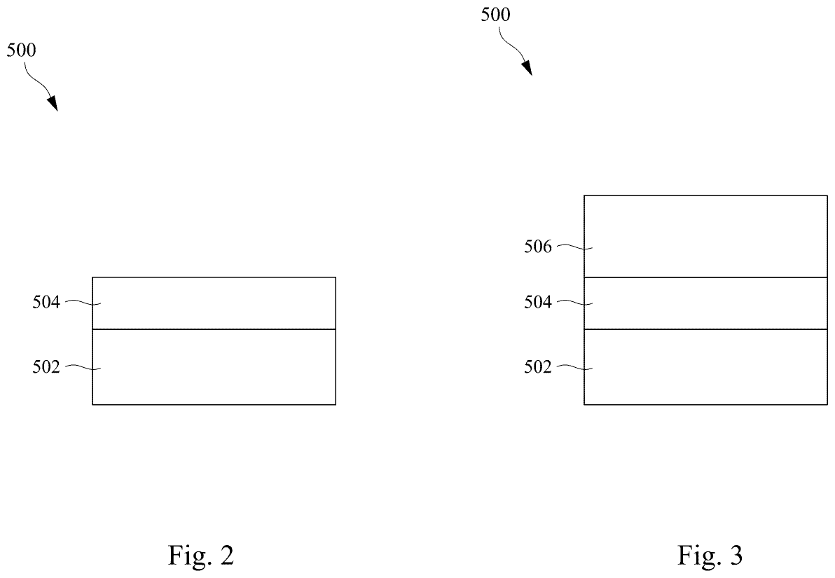

The various aspects of the present disclosure will be discussed below in greater detail with reference to FIGS. 1A-23C. First, an EUV lithography system will be discussed below with reference to FIGS. 1A, 1B and 1C. Next, the details of the novel photoresist composition and the lithography process employing the photoresist composition will be discussed with reference to FIGS. 2-23C.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a laser-produced plasma (LPP) are collected by a collector mirror and reflected toward a patterned mask.

FIG. 1A is a schematic view of an EUV lithography tool with an LPP-based EUV radiation source, in accordance with some embodiments of the present disclosure. The EUV lithography system includes an EUV radiation source 100 to generate EUV radiation, an exposure device 200, such as a scanner, and an excitation laser source 300. As shown in FIG. 1A, in some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 1C, the EUVL tool includes an EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic”, as used herein, is directed to, but not limited to, components which operate solely or to advantage within one or more specific wavelength range(s) such as at the EUV output light wavelength, the irradiation laser wavelength, a wavelength suitable for metrology or any other specific wavelength. In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. A droplet generator 115 is turned on to eject the target droplets DP toward the zone of excitation ZE in front of the collector 110. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a ML (such as a plurality of Mo/Si film pairs) and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask 205c. The reflective mask 205c also includes a reflective ML deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs, or other suitable materials that are configurable to highly reflect the EUV light.

The mask 205c may further include a capping layer, such as ruthenium (Ru), disposed on the ML for protection. The mask 205c further includes an absorption layer deposited over the ML. The absorption layer is patterned to define a layer of an integrated circuit (IC), the absorber layer is discussed below in greater detail according to various aspects of the present disclosure. Alternatively, another reflective layer may be deposited over the ML and is patterned to define a layer of an integrated circuit, thereby forming a EUV phase shift mask.

The mask 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of the reflective mask 205c is shown in FIG. 1C. The reflective mask 205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the LTEM substrate 30 for the electrostatic chucking purpose. In one example, the conductive layer 32 includes chromium nitride (CrN), though other suitable compositions are possible.

The reflective mask 205c includes a reflective multilayer (ML) structure 34 disposed over the LTEM substrate 30. The ML structure 34 may be selected such that it provides a high reflectivity to a selected radiation type/wavelength. The ML structure 34 includes a plurality of film pairs, such as Mo/Si film pairs (e.g., a layer of molybdenum above or below a layer of silicon in each film pair). Alternatively, the ML structure 34 may include Mo/Be film pairs, or any materials with refractive index difference being highly reflective at EUV wavelengths.

Still referring to FIG. 1C, the EUV mask 205c also includes a capping layer 36 disposed over the ML structure 34 to prevent oxidation of the ML. The EUV mask 205c may further include a buffer layer 38 disposed above the capping layer 36 to serve as an etching-stop layer in a patterning or repairing process of an absorption layer, which will be described later. The buffer layer 38 has different etching characteristics from the absorption layer disposed thereabove. The buffer layer 38 includes ruthenium (Ru), Ru compounds such as RuB, RuSi, chromium (Cr), chromium oxide, and chromium nitride in various examples.

The EUV mask 205c also includes an absorber layer 40 (also referred to as an absorption layer) formed over the buffer layer 38. In some embodiments, the absorber layer 40 absorbs the EUV radiation directed onto the mask. In various embodiments, the absorber layer may be made of tantalum boron nitride (TaBN), tantalum boron oxide (TaBO), or chromium (Cr), Radium (Ra), or a suitable oxide or nitride (or alloy) of one or more of the following materials: Actium, Radium, Tellurium, Zinc, Copper, and Aluminum.

FIGS. 2-3 and 5-7 illustrate fragmentary cross-sectional side views of a semiconductor device 500 in accordance with various aspects of the present disclosure. In FIGS. 2-3 and 5-7, the semiconductor device 500 can be fabricated using a photoresist layer 506. Referring first to FIG. 2, a target layer 504 is formed over a substrate 502. The semiconductor device 500 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistors.

In some embodiments, the substrate 502 is a silicon substrate doped with a p-type dopant such as boron (for example a p-type substrate). Alternatively, the substrate 502 could be another suitable semiconductor material. For example, the substrate 502 may be a silicon substrate that is doped with an n-type dopant such as phosphorous or arsenic (an n-type substrate). The substrate 502 could include other elementary semiconductors such as germanium and diamond. The substrate 502 could optionally include a compound semiconductor and/or an alloy semiconductor. Further, the substrate 502 could include an epitaxial layer (epi layer), may be strained for performance enhancement, and may include a silicon-on-insulator (SOI) structure.

In some embodiments, the substrate 502 is substantially conductive or semi-conductive. The electrical resistance may be less than about 103 ohm-meter. In some embodiments, the substrate 502 contains metal, metal alloy, or metal nitride/sulfide/selenide/oxide/silicide with the formula MXa, where M is a metal, and X is N, S, Se, O, Si, and where “a” is in a range from about 0.4 to 2.5. For example, the substrate 502 may contain Ti, Al, Co, Ru, TiN, WN₂, or TaN.

In some other embodiments, the substrate 502 contains a dielectric material with a dielectric constant in a range from about 1 to about 40. In some other embodiments, the substrate 502 contains Si, metal oxide, or metal nitride, where the formula is MXb, wherein M is a metal or Si, and X is N or O, and wherein “b” is in a range from about 0.4 to 2.5. For example, the substrate 502 may contain SiO₂, silicon nitride, aluminum oxide, hafnium oxide, or lanthanum oxide.

The target layer 504 can be patterned via a lithography process and as such may also be referred to as a patternable layer. In an embodiment, the target layer 504 includes a dielectric material, such as silicon oxide or silicon nitride. In another embodiment, the target layer 504 includes metal. In yet another embodiment, the target layer 504 includes a semiconductor material.

In some embodiments, the target layer 504 has different optical properties than photoresist. For example, the target layer 504 has a different n, k, or T value from photoresist. In some embodiments, the target layer 504 and the overlying photoresist layer have different etching resistance. In some embodiments, the target layer 504 contains an etching resistant molecule. It is understood that the substrate 502 and the target layer 504 may each include additional suitable material compositions in other embodiments.

Reference is made to FIG. 3. In some embodiments, a photoresist composition can be applied over the target layer 504 to form a photoresist layer 506. In some embodiments, the photoresist composition can include a first metallic photoresist and a second metallic photoresist in which the first metallic photoresist includes a composition different from a composition of the second metallic photoresist. In some embodiments, the first metallic photoresist can be a 12-Tin-oxo cluster, such as having a formula (1):

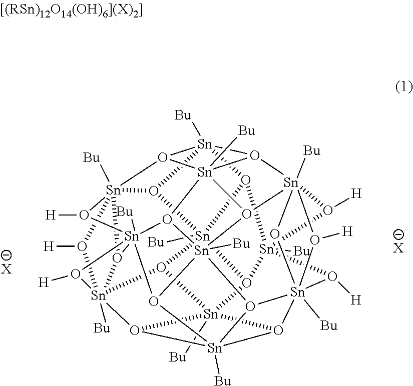

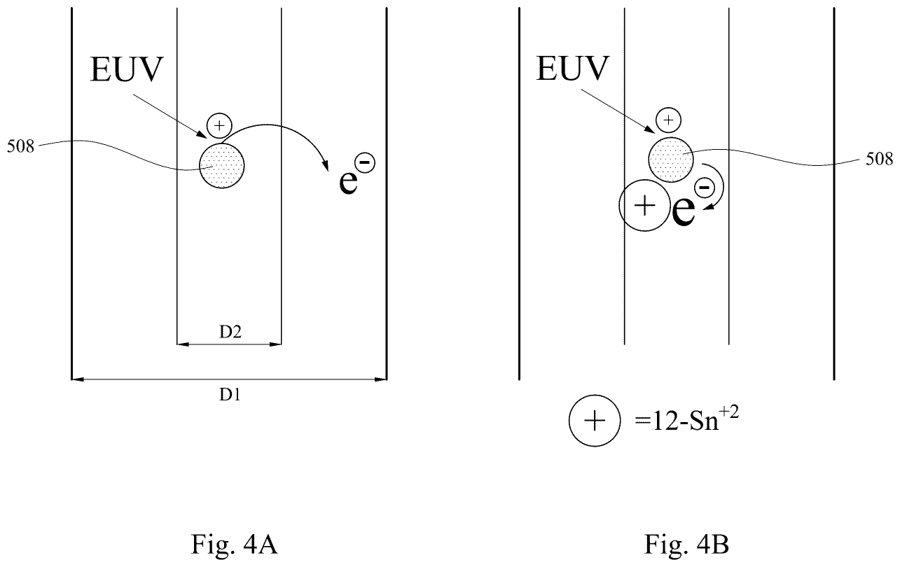

(1). FIGS. 4A-4B show a mechanism of the ejection of an electron of the photoresist layer 506 upon absorbing the EUV radiation in accordance with some embodiments. Reference is made to FIGS. 4A-4B. The first metallic photoresist can have a large amount of dications, such as 12-Sn²⁺. Atoms 508 of the first metallic photoresist or the second metallic photoresist can absorb the EUV radiation and eject electrons, and the ejected electrons can fall in a small EUV-exposure domain D2 smaller than an EUV-exposure domain D1 (such as about 48 nm), such as HP of about 16 nm, and interact with the 12-Sn²⁺ of the first metallic photoresist, increasing the electron affinity. Accordingly, the electron of the photoresist composition can have a large barrier to eject electrons, which is beneficial for keeping a large portion of electrons with the small zone (the HP of about 16 nm).

The second metallic photoresist can be a 6Sn-2Cl cluster. In some embodiments, the second metallic photoresist can have formula (2), formula (2′), formula (2″), or a combination thereof:
(RSn)₆O₄C₁₂(R′CO₂)₈(2); (RSn)₆₋ₓ(R′Sn)ₓO₄Cl₂(R″CO₂)₈ (2′) (RSn)₆O₄C₁₂(R′CO₂)₈₋ₓ(R″CO₂)ₓ (2″). That is, the second metallic photoresist can include multiple types of Sn species or mixed types of Sn species (see the formula (2′). Further, the second metallic photoresist can include multiple types of carboxylic ligands or mixed types of carboxylic ligands (see the formula (2″). Each of the formulae (2) and (2′) has a number of Sn atoms less than a number of Sn atoms of the formula (1). In the formulae (1), (2), (2′) and (2″), R, R′ or R″ can be independently alkyl, alkenyl, or the like, and X in the formula (1) can be BF₄, OTf (OTf=Trifluoromethanesulfonate or triflate), SbF₆ or the like. In some embodiments, a weight ratio of the first metallic photoresist to the second metallic photoresist can be about 0.1 to about 10. In some embodiments, the first metallic photoresist and the second metallic photoresist can collectively be about 1% to about 3%, such as about 1% to about 2.5% in total weight of the photoresist composition. If this weight ratio is less than about 1%, the film thickness of the photoresist layer 506 may be too thin. If this weight ratio is greater than about 3%, the film thickness of the photoresist layer 506 may be too large, such as exceed about 40 nm. By including the second metallic photoresist in the photoresist composition, the photoactive property for the photosensitive composition can be improved.

In some embodiments, the photoresist composition can include the first metallic photoresist having a 12Sn—BF₄ cluster in which the X in the formula (1) is BF₄ and the second metallic photoresist can include a formula (2a), which is an example of the formula (2): (vinylSn)₆O₄Cl₂(sec-butylCO₂)₈ formula (2a), and a weight ratio of the 12Sn—BF₄ cluster and the second metallic photoresist with the formula (2a) can be about 2:1 and be patterned into a pattern with a HP of about 13 nm to about 16 nm, such as 15 nm, obtained at an EUV energy dose of 54±10 mJ/cm² which is much lower than 200 to 220 mJ/cm² required for exposing only the first metallic photoresist. In some embodiments, the photoresist composition includes a solid content including SnO₂ and BF₄ with a ratio of about 76%.

In some embodiments, the photoresist composition includes the first metallic photoresist having a 12Sn—BF₄ cluster in which the X in the formula (1) is BF₄ and the second metallic photoresist includes 6-Sn-2Cl cluster, for example, a formula (2b), which is an example of the formula (2): (vinylSn)₆O₄Cl₂(sec-C₄H₇CO₂)₈ formula (2b). The weight ratio of the 12Sn—BF₄ cluster and the second metallic photoresist with the formula (2b) can be about 2:1 and be patterned into a pattern with a half-pitch (HP) of about 18 nm to about 25 nm, such as 18 nm, obtained at an EUV energy dose of about 42 mJ/cm² to about 49 mJ/cm², such as about 42 mJ/cm². In the formula (2b), the sec-C₄H—CO₂ can be represented by a formula (a):

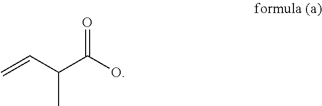

In some embodiments, the photoresist composition includes the first metallic photoresist having a 12Sn—BF₄ cluster in which the X in the formula (1) is BF₄ and the second metallic photoresist includes 6-Sn-2Cl cluster, for example, a formula (2a′), which is an example of the formula (2″):
(vinylSn)₆O₄Cl₂(sec-C₄H₇CO₂)₄(sec-C₄H₉CO₂)₄ formula (2a′). The weight ratio of the 12Sn—BF₄ cluster and the second metallic photoresist with the formula (2a′) can be about 1:2 and be patterned into a pattern with a HP of about 15 nm to about 22 nm, obtained at an EUV energy dose of about 60 mJ/cm² to about 65 mJ/cm², such as about 65 mJ/cm² and have a solid content including SnO₂ and BF₄ with a ratio of about 74%, greater than a solid content of only applying the second metallic photoresist with the formula (2a′), which is about 42±5%.

The second metallic photoresist can be an HfO₂-based photoresist. In some embodiments, the second metallic photoresist can include a Hf oxide cluster including a formula (3) or a formula (3′):
Hf₆O₄(OH)₈(RCO₂)₈ (3); Hf₆O₄(OH)₈(R′CO₂)₈₋ₓ(R″CO₂)ₓ (3′). That is, the second metallic photoresist can include one type of carboxylic ligand (see the formula (3) or multiple types of carboxylic ligands or mixed types of carboxylic ligands (see the formula (3′). Each of the formulae (3) and (3′) has a number of Hf atoms less than a number of Sn atoms of the formula (1). In the formulae (3) and (3′), R, R′ or R″ can be independently alkyl, alkenyl, or the like. In some embodiments, a weight ratio of the first metallic photoresist to the second metallic photoresist can be about 0.10 to about 10. In some embodiments, the first metallic photoresist and the second metallic photoresist can collectively be about 1% to about 3% in total weight of the photoresist composition. The second metallic photoresist has a good photosensitive property and thus can provide improved photoactive property for the photoresist composition.

In some embodiments, the photoresist composition includes the first metallic photoresist having a 12Sn—BF₄ cluster in which the X in the formula (1) is BF₄ and the second metallic photoresist includes a 6-Hf oxide cluster, for example, a formula (3a), which is an example of the formula (3)
Hf₆O₄(OH)₈(sec-C₄H—CO₂)₈ (3a), and the weight ratio of the 12Sn—BF₄ cluster and the second metallic photoresist with the formula (3a) can be about 1:2. The photoresist layer 506 can be patterned into a pattern with an HP of about 14 nm to about 25 nm, such as about 14 nm, obtained at an EUV energy dose of about 76 mJ/cm² to about 94 mJ/cm², such as about 94 mJ/cm². The second metallic photoresist can provide increased dry etch resistance for the photoresist layer 506 since Hf oxide or HfO₂-based photoresist have high atomic weight (e.g., 178 g/mole).

The second metallic photoresist can be a 6Sn-oxide cluster. In some embodiments, the second metallic photoresist can include a carboxylate-free 6-Sn oxide cluster including a formula (4), a formula (4′), a formula (5) or a formula (5′):
(RSn)₆O₄(OH)₁₀ (4); (RSn)ₓ(R′Sn)₆₋ₓO₄(OH)₁₀ (4′); (RSn)₆O₄(RCO₂)ₓ(OH)₁₀₋ₓ (5); and (RSn)₆(R′Sn)₆₋ₓO₄(R″CO₂)ₓ (OH)₁₀₋ₓ (5′). That is, the second metallic photoresist can include one type of Sn species (see the formula (4)) or multiple types of Sn species and mixed types of Sn species (see the formula (4′)). The second metallic photoresist can include one type of carboxylic ligand (see the formula (5)). The second metallic photoresist can include multiple types of Sn species and one type of carboxylic ligand (see the formula (5′)). In the formulae (4), (4′), (5) and (5′), x can be 1.0 to 5.0, and R, R′ or R″ can be independently alkyl, alkenyl, or the like. In some embodiments, a weight ratio of the first metallic photoresist to the second metallic photoresist can be about 0.10 to about 10. In some embodiments, the first metallic photoresist and the second metallic photoresist can collectively be about 1% to about 3% in total weight of the photoresist composition. By including the second metallic photoresist in the photoresist composition, the photoactive property for the photosensitive composition can be improved.

In some embodiments, the photoresist composition includes the first metallic photoresist having a 12Sn—BF₄ cluster in which the X in the formula (1) is BF₄ and the second metallic photoresist includes 6-Sn oxide cluster, for example, having a formula (5a), which is an example of the formula (5)
Sn₆(C₃H₅)₁(C₄H₉)₅O₄(CH₃CO₂)₂(OH)₈ formula (5a), and the weight ratio of the 12Sn—BF₄ cluster and the second metallic photoresist with the formula (5a) can be about 1:3 and be patterned into a pattern with an HP of about 30±2 nm, obtained at an EUV energy dose of 480±10 μC/cm². In some embodiments, the photoresist composition includes the first metallic photoresist having a 12Sn—BF₄ cluster in which the X in the formula (1) is BF₄ and the second metallic photoresist includes 6-Sn oxide cluster, for example, a formula (5b), which is another example of the formula (5):
Sn₆(C₃H₅)₆(CH₃COO)₆O₄(OH)₄ formula (5b), and a weight ratio of the 12Sn—BF₄ cluster and the second metallic photoresist with the formula (5b) can be about 1:1. In case of using e-beam to expose the photoresist layer, the e-beam energy dose can be 640±10 μC/cm² to reach a pattern including a HP of about 30 nm. Such photoresist composition can provide increased SnO₂ content higher than SnO₂ content of using only the second metallic photoresist including the formula (2).

In some embodiments, the solvent for an adjustment of the viscosity of the photoresist composition can include 4-methyl-2-pentanol or other suitable solvents. In some embodiments, formation of the photoresist composition includes blending the first metallic photoresist and the second metallic photoresist to form a mixture and then dissolve the mixture with the solvent. In some embodiments, the mixture formed by the first metallic photoresist and the second metallic photoresist can have a weight ratio of about 0.5% to about 3.0% in the solvent. If this weight ratio is less than about 0.5%, the film thickness of the photoresist layer 506 may be too thin. If this weight ratio is greater than about 3.0%, the film thickness of the photoresist layer 506 may be too may be too large. The photoresist layer 506 may be formed by a spin-coating process. In some embodiments, the photoresist layer 506 can be spin coated on the target layer 504 on the substrate 502. In many instances, the substrate 502 when in the form of a wafer can have a diameter of 4-inch (100 mm); 5-inch (130 mm) or 125 mm (4.9 inch); 150 mm (5.9 inch, usually referred to as “6 inch”); 200 mm (7.9 inch, usually referred to as “8 inch”); or 300 mm (11.8 inch, usually referred to as “12 inch”), for example. The photoresist compositions can be applied at a 1500±50 rotations per minute (rpm) for 10±2 seconds and then at 2000±50 rotations per minute (rpm) for 25±2 seconds.

In some embodiments, a post apply bake (PAB) (or soft bake) can be performed to the photoresist layer 506 for about 1 minute at a temperature in a range from about 60° C. to about 180° C., resulting in a film thickness of about 20 nm to about 40 nm for the photoresist layer 506.

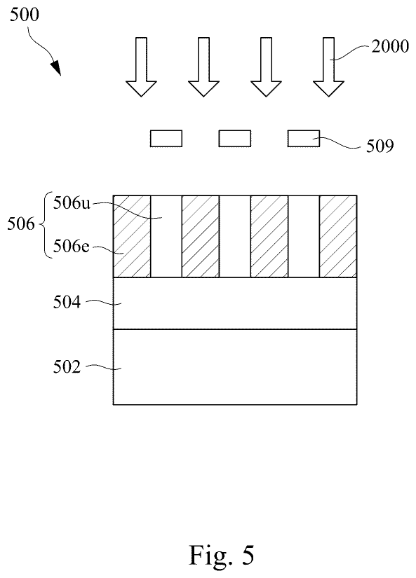

Reference is made to FIG. 5. An exposure process 2000 can be performed to the photoresist layer 506. The photoresist layer 506 can have exposed regions 506e which are uncovered by a mask 509 including the design of a layer of an IC and thus are exposed by the exposure process 2000. The photoresist layer 506 can have an un-exposed regions 506u covered by the mask 509 during the exposure process 2000. In some embodiments, the photoresist layer 506 can be exposed to EUV radiation during the exposure process 2000. In some embodiments, a post-exposure bake (PEB) may then be performed to the photoresist layer 506 at a temperature in a range from about 100° C. to about 180° C. for about one minute.

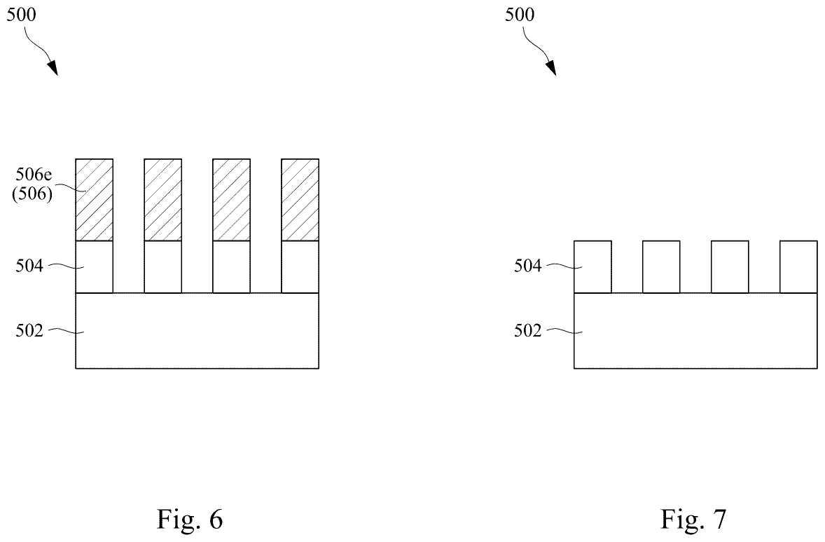

Reference is made to FIG. 6. In some embodiments, the photoresist layer 506 is developed, such as using a developer, forming the patterned photoresist layer 506, for a duration of about, for example, one minute. In some embodiments, the developer may include propylene glycol monomethyl ether (PGME), 2-heptanone, or the like. In some embodiments, a post-develop bake operation is performed to the photoresist layer 506 at a temperature in a range from about 90° C. to about 110° C. The photoresist layer 506 can include SnₓOₓCl_{y} or HfₓSn_{y}XO_{z} instead of SnO₂ in which X can be BF₄ and SbF₆ instead of SnO₂.

The target layer 504 can be etched by using the patterned photoresist layer 506 as an etch mask. The patterned photoresist layer 506 is then removed, for example, by ashing. The ashing operation such as a plasma ash removes the remaining patterned photoresist layer 506, and a wet clean may be performed to clean the etch residues. The resulting structure is shown in FIG. 7.

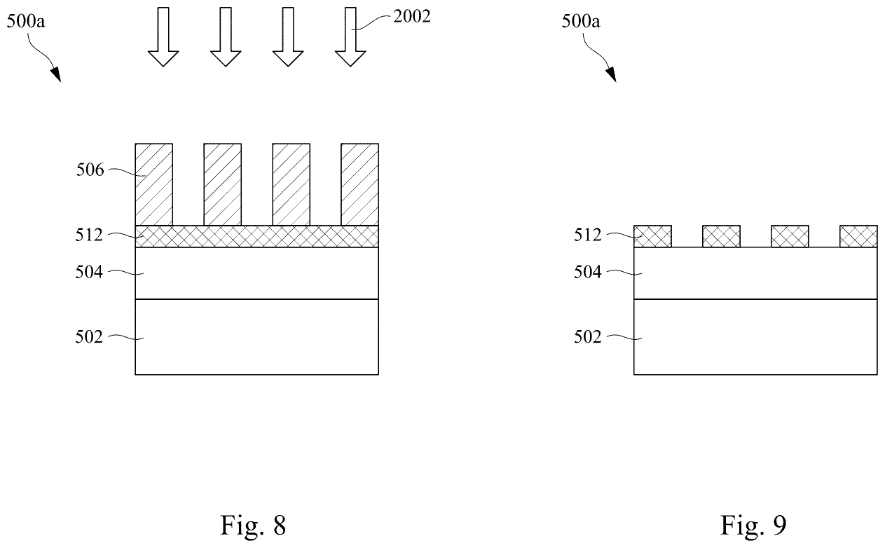

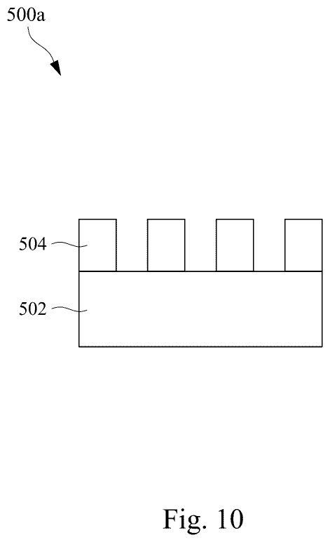

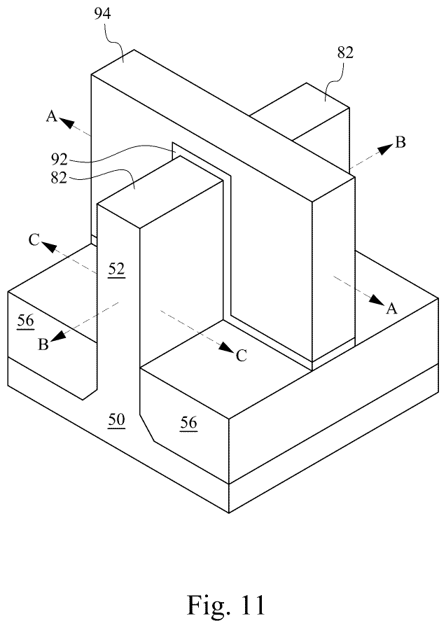

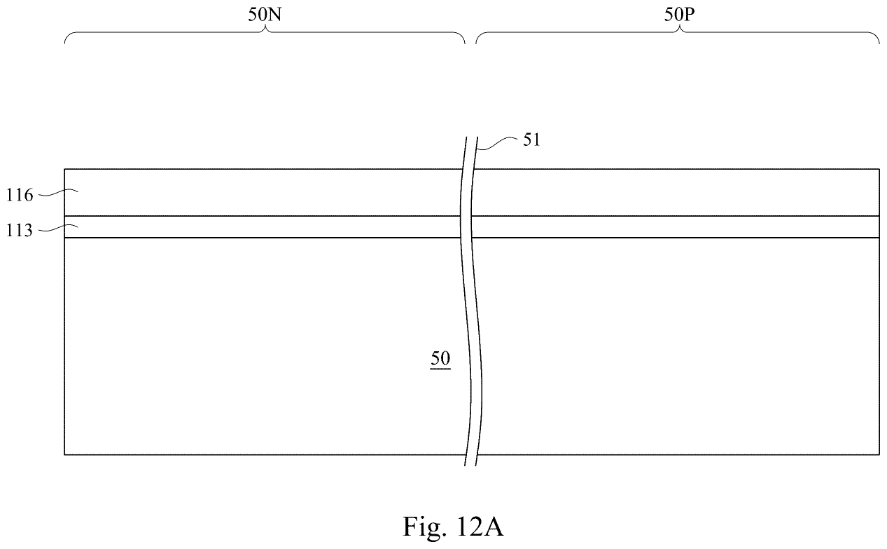

FIGS. 8-10 illustrate fragmentary cross-sectional side views of a semiconductor device 500a in accordance with various aspects of the present disclosure. In FIG. 8, in some embodiments, a bottom anti-reflective coating (BARC) layer 512 can be formed over the target layer 504 and the photoresist composition can then be applied over the BARC layer 512 to form a photoresist layer 506. The BARC layer 512 may provide for absorption of radiation incident to the target layer 504 during photolithography processes, including exposure of the overlying photoresist layer 506. The BARC layer 512 may have a different refractive index (n), a different extinction coefficient (k), or thickness (T) value and a different etch resistance than the photoresist layer 506. The BARC layer 512 may be blanket deposited using, for example, spin-on processes. Other processes and materials may be used. The photoresist layer 506 can then be exposed and developed, as discussed previously with regard to FIGS. 5-6, and the BARC layer 512 can be etched by using the photoresist layer 506 as an etch mask. The resulting structure is shown in FIG. 9. The target layer 504 can then be etched by using the BARC layer 512 as an etch mask. The BARC layer 512 is then removed by suitable ashing methods or etching methods. The resulting structure is shown in FIG. 10.

FIG. 11 illustrates an example of a FinFET in a three-dimensional view, in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and gate electrode 94. FIG. 9 further illustrates reference cross-sections that are used in later figures. Cross-section A-A is along a longitudinal axis of the gate electrode 94 and in a direction, for example, perpendicular to the direction of current flow between the source/drain regions 82 of the FinFET. Cross-section B-B is perpendicular to cross-section A-A and is along a longitudinal axis of the fin 52 and in a direction of, for example, a current flow between the source/drain regions 82 of the FinFET. Cross-section C-C is parallel to cross-section A-A and extends through a source/drain region of the FinFET. Subsequent figures refer to these reference cross-sections for clarity.

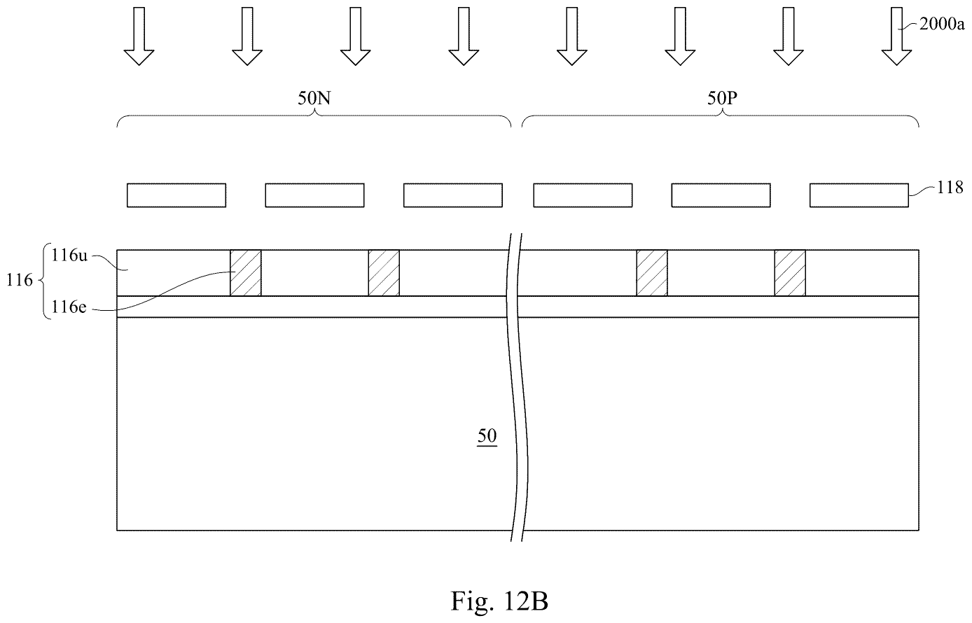

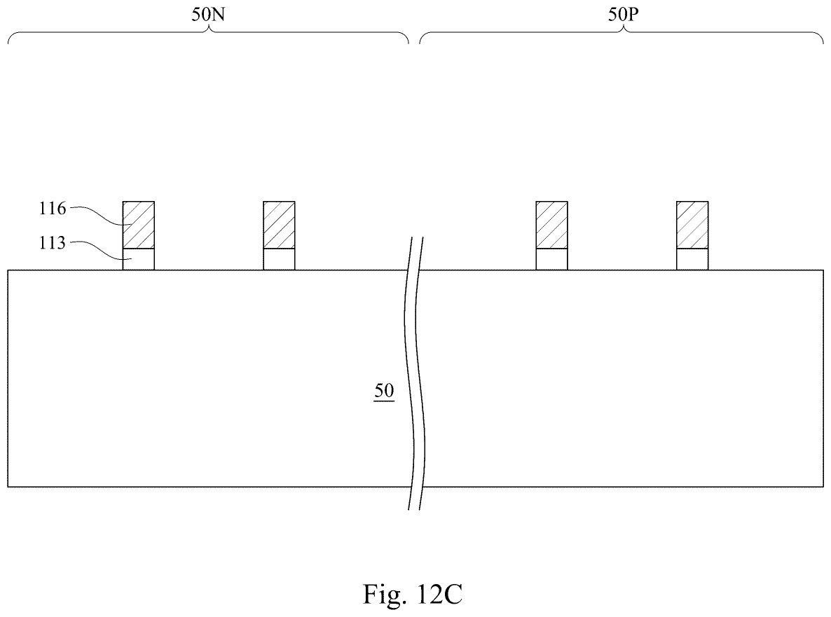

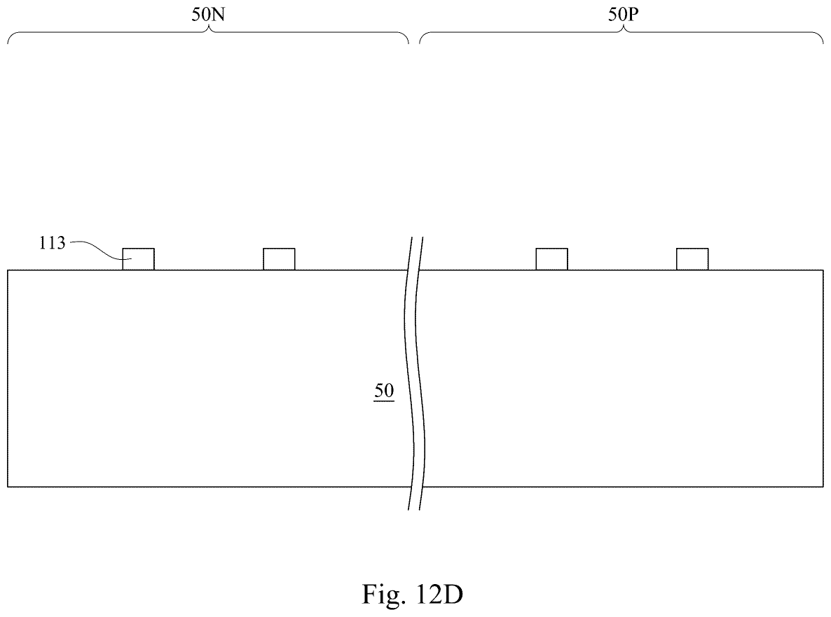

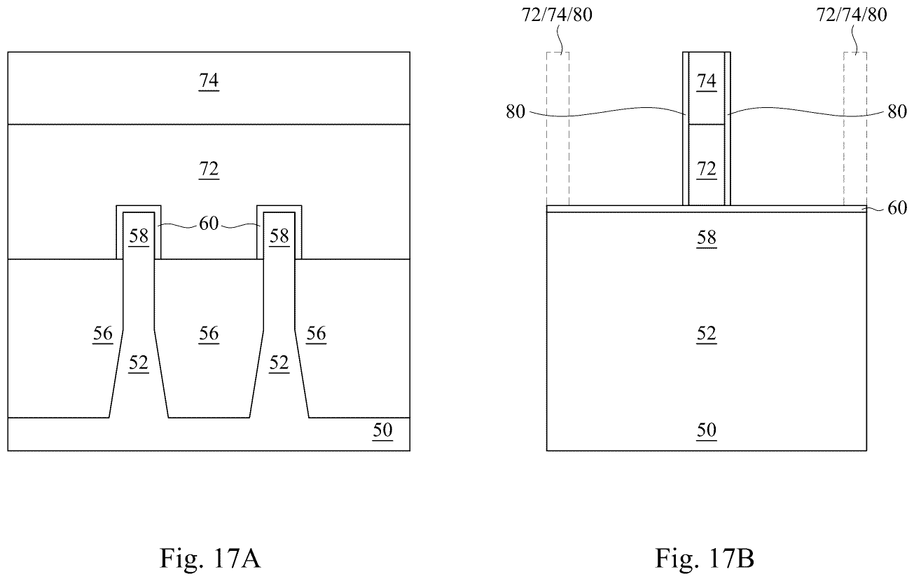

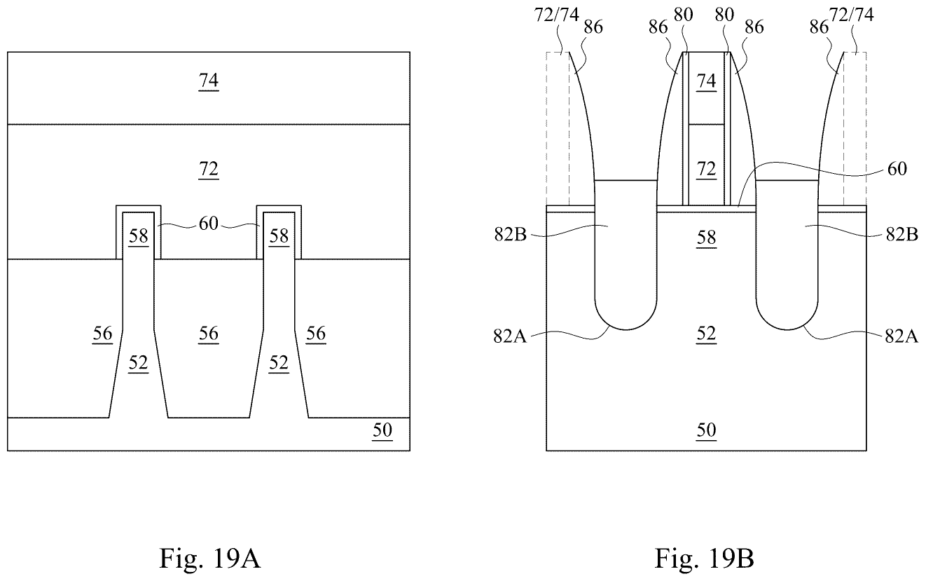

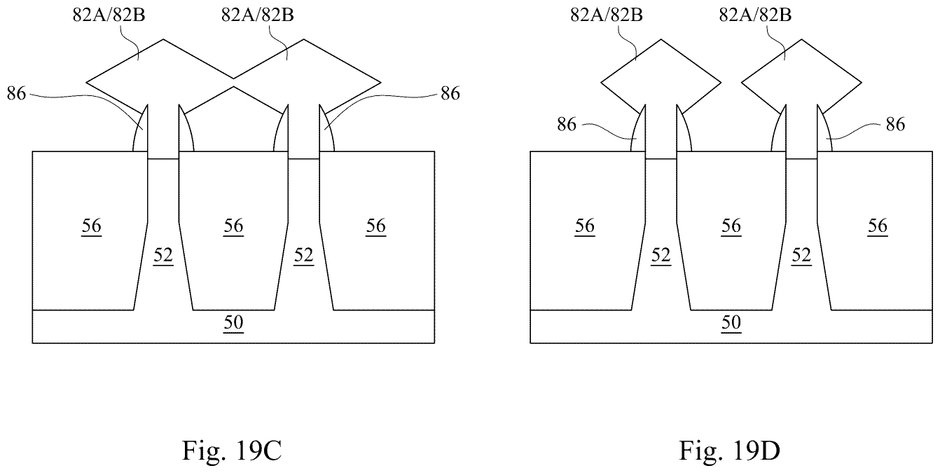

FIGS. 12A, 12B, 12C, 12D and 13-23C are cross-sectional views of intermediate stages in the manufacturing of FinFETs, in accordance with some embodiments. FIGS. 12A-12D and 13-16 illustrate reference cross-section A-A illustrated in FIG. 11, except for multiple fins/FinFETs. FIGS. 17A, 18A, 19A, 20A, 21A, 22A and 23A are illustrated along reference cross-section A-A illustrated in FIG. 9, and FIGS. 17B, 18B, 19B, 20B, 21B, 22B and 23B are illustrated along a similar cross-section B-B illustrated in FIG. 11, except for multiple gate structures. FIGS. 19C and 19D are illustrated along reference cross-section C-C illustrated in FIG. 11, except for multiple fins/FinFETs.

FIGS. 12A-12C are cross-sectional views of forming a patterned photoresist layer in accordance with some embodiments. Reference is made to FIG. 12A. A substrate 50 is provided. The substrate 50 may be similar to the substrate 502 in FIG. 2, and thus the description thereof is omitted herein. The substrate 50 has a region 50N and a region 50P. The region 50N can be for forming n-type devices, such as n-type MOS (NMOS) transistors, e.g., n-type FinFETs. The region 50P can be for forming p-type devices, such as p-type MOS (PMOS) transistors, e.g., p-type FinFETs. The region 50N may be physically separated from the region 50P (as illustrated by divider 51), and any number of device features (e.g., other active devices, doped regions, isolation structures, etc.) may be disposed between the region 50N and the region 50P. In some embodiments, a bottom anti-reflective coating (BARC) layer 113 can be formed over the substrate 50 and the photoresist composition can then be applied over the BARC layer 512 to form a photoresist layer 116. The BARC layer 113 and the photoresist layer 116 are similar to the BARC layer 512 and the photoresist layer 506, respectively, in FIG. 8 in terms of composition and formation methods, and thus the description thereof is omitted herein. A soft bake operation may then be performed to the photoresist layer 116.

Reference is made to FIG. 12B. In some embodiments, the photoresist layer 116 is exposed by an exposure process 2000a using an actinic radiation, such as an EUV radiation, and has an exposed region 116e and a un-exposed region 116u. As discussed previously, the photoresist layer 116 formed by the first metallic photoresist and the second metallic photoresist can be exposed using low EUV energy dose to obtain a high EUV resolution pattern and have an increased etching rate due to its increased metal content. The photoresist layer 116 can then be developed, as shown in FIG. 12C. The photoresist layer 116 can include SnₓOₓCl_{y} or HfₓSn_{y}XO_{z} instead of SnO₂ in which X can be BF₄ and SbF₆ instead of SnO₂.

Reference is made to FIG. 12C. In some embodiments, the BARC layer 113 is then etched by using the photoresist layer 116 as an etch mask. The photoresist layer 114 can be removed after etching the BARC layer 113 by using a suitable photoresist stripper solvent or by a photoresist ashing operation. The resulting structure is shown in FIG. 12D.

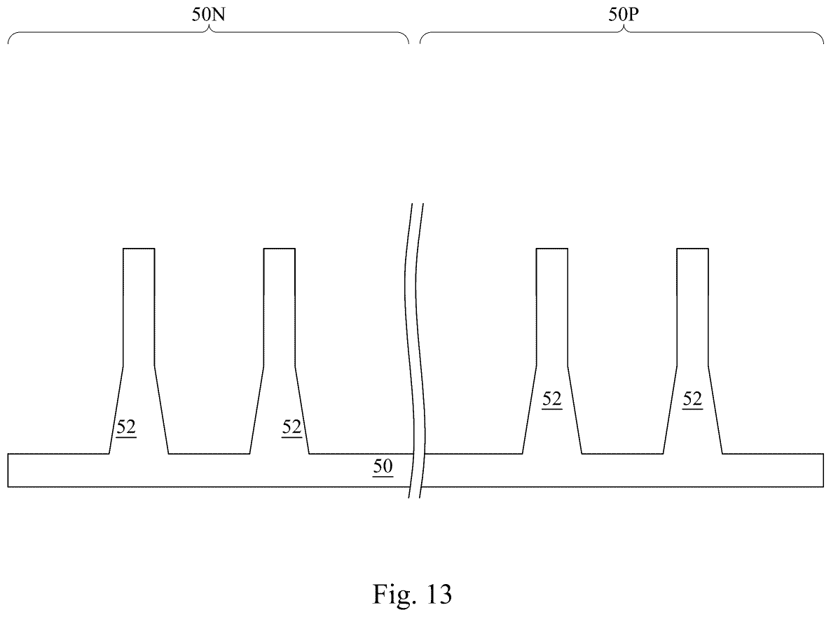

Reference is made to FIG. 13. The substrate 50 can be etched using the BARC layer 113 as an etched mask. The BARC layer 113 can be removed after etching the substrate 50 by using suitable ashing methods or etching methods.

In FIG. 13, fins 52 are formed in the substrate 50. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

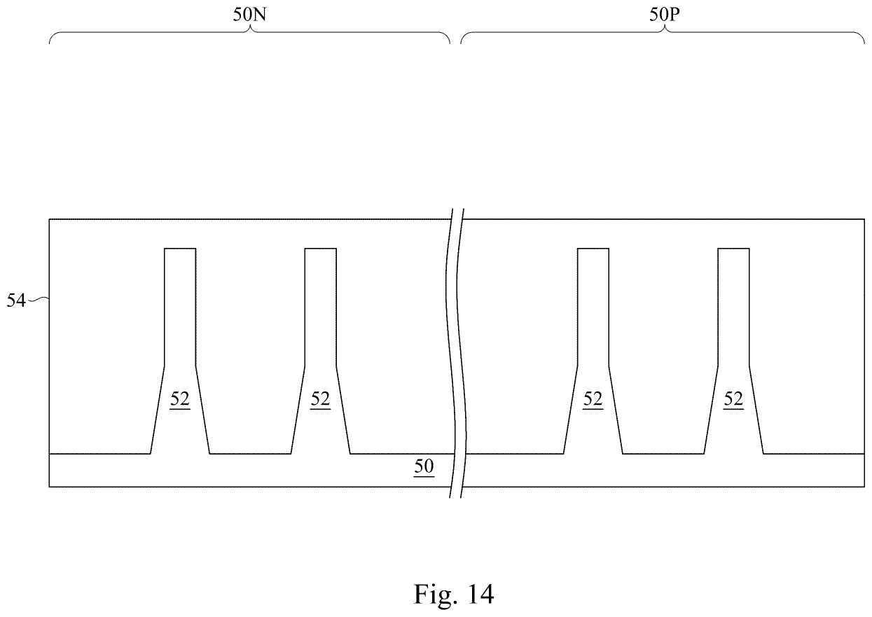

In FIG. 14, an insulation material 54 is formed over the substrate 50 and between neighboring fins 52. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments a liner (not shown) may first be formed along a surface of the substrate 50 and the fins 52. Thereafter, a fill material, such as those discussed above may be formed over the liner.

A removal process is applied to the insulation material 54 to remove excess insulation material 54 over the fins 52. In some embodiments, a planarization process such as a chemical mechanical polish (CMP), an etch-back process, combinations thereof, or the like may be utilized. The planarization process exposes the fins 52 such that top surfaces of the fins 52 and the insulation material 54 are level after the planarization process is complete. In embodiments in which a mask remains on the fins 52, the planarization process may expose the mask or remove the mask such that top surfaces of the mask or the fins 52, respectively, and the insulation material 54 are level after the planarization process is complete.

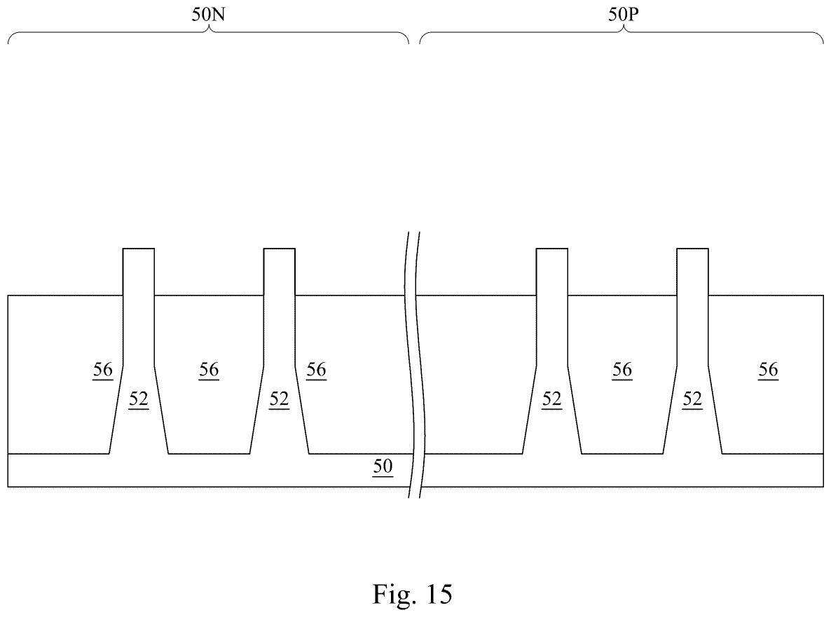

In FIG. 15, the insulation material 54 is recessed to form Shallow Trench Isolation (STI) regions 56. The insulation material 54 is recessed such that upper portions of fins 52 in the region 50N and in the region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, an oxide removal using, for example, dilute hydrofluoric (dHF) acid may be used.

Further in FIG. 15, appropriate wells (not shown) may be formed in the fins 52 and/or the substrate 50. In some embodiments, a P well may be formed in the region 50N, and an N well may be formed in the region 50P. In some embodiments, a P well or an N well are formed in both the region 50N and the region 50P.

In the embodiments with different well types, the different implant steps for the region 50N and the region 50P may be achieved using a photoresist or other masks (not shown). For example, a photoresist may be formed over the fins 52 and the STI regions 56 in the region 50N. The photoresist is patterned to expose the region 50P of the substrate 50, such as a PMOS region. The photoresist can be formed by using a spin-on technique and can be patterned using acceptable photolithography techniques. Once the photoresist is patterned, an n-type impurity implant is performed in the region 50P, and the photoresist may act as a mask to substantially prevent n-type impurities from being implanted into the region 50N, such as an NMOS region. The n-type impurities may be phosphorus, arsenic, antimony, or the like. After the implant, the photoresist is removed, such as by an acceptable ashing process.

Following the implanting of the region 50P, a photoresist is formed over the fins 52 and the STI regions 56 in the region 50P. The photoresist is patterned to expose the region 50N of the substrate 50, such as the NMOS region. The photoresist can be formed by using a spin-on technique and can be patterned using acceptable photolithography techniques. Once the photoresist is patterned, a p-type impurity implant may be performed in the region 50N, and the photoresist may act as a mask to substantially prevent p-type impurities from being implanted into the region 50P, such as the PMOS region. The p-type impurities may be boron, boron fluoride, indium, or the like. After the implant, the photoresist may be removed, such as by an acceptable ashing process.

After the implants of the region 50N and the region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

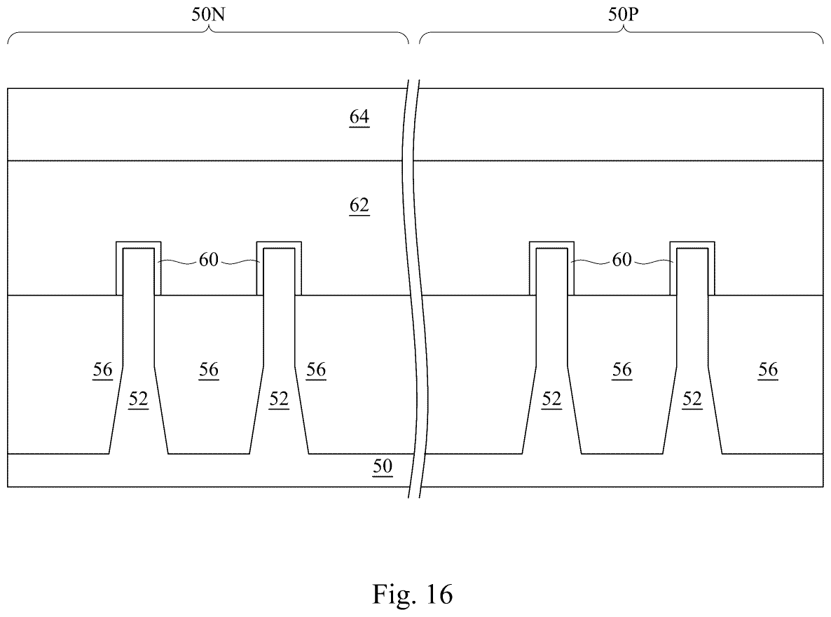

In FIG. 16, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques known and used in the art for depositing the selected material. The dummy gate layer 62 may be made of other materials that have a high etching selectivity from the etching of isolation regions. The mask layer 64 may include, for example, silicon nitride, silicon oxynitride, or the like. In this example, a single dummy gate layer 62 and a single mask layer 64 are formed across the region 50N and the region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending between the dummy gate layer 62 and the STI regions 56.

In FIG. 16, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques known and used in the art for depositing the selected material. The dummy gate layer 62 may be made of other materials that have a high etching selectivity from the etching of isolation regions. The mask layer 64 may include, for example, silicon nitride, silicon oxynitride, or the like. In this example, a single dummy gate layer 62 and a single mask layer 64 are formed across the region 50N and the region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending between the dummy gate layer 62 and the STI regions 56.

FIGS. 17A through 23C illustrate features in either of the region 50N and the region 50P. For example, the structures illustrated in FIGS. 17A through 23C may be applicable to both the region 50N and the region 50P. Differences (if any) in the structures of the region 50N and the region 50P are described in the text accompanying each figure.

In FIGS. 17A and 17B, the mask layer 64 (see FIG. 16) may be patterned using acceptable photolithography and etching techniques to form masks 74. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective fins 52.

Further in FIGS. 17A and 17B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, a mask, such as a photoresist, may be formed over the region 50N, while exposing the region 50P, and appropriate type (e.g., p-type) impurities may be implanted into the exposed fins 52 in the region 50P. The mask may then be removed. Subsequently, a mask, such as a photoresist, may be formed over the region 50P while exposing the region 50N, and appropriate type impurities (e.g., n-type) may be implanted into the exposed fins 52 in the region 50N. The mask may then be removed. The n-type impurities may be the any of the n-type impurities previously discussed, and the p-type impurities may be the any of the p-type impurities previously discussed. An anneal may be used to repair implant damage and to activate the implanted impurities.

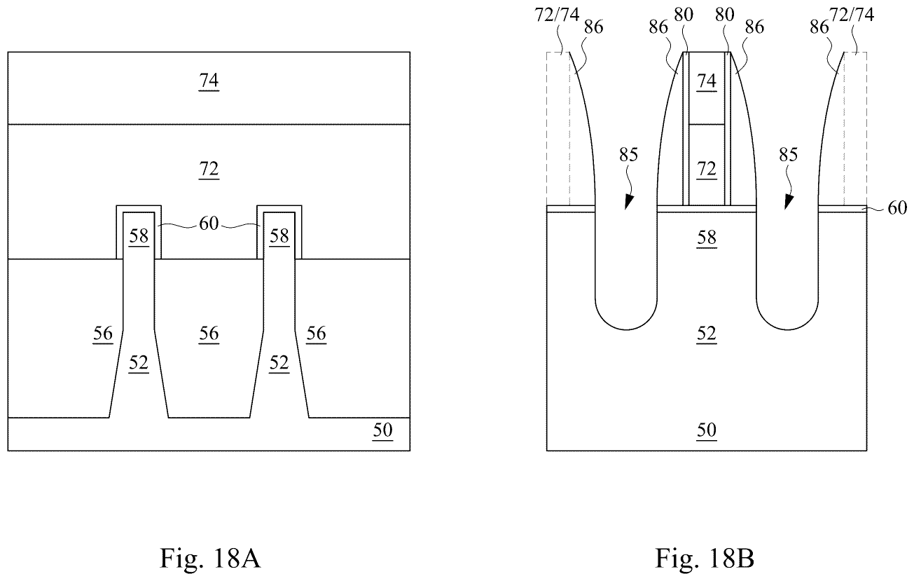

In FIGS. 18A and 18B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may be silicon oxide, silicon nitride, silicon oxynitride, silicon carbonitride, a combination thereof, or the like.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers, spacers may be formed and removed, and/or the like.) Furthermore, the n-type and p-type devices may be formed using a different structures and steps. For example, LDD regions for n-type devices may be formed prior to forming the gate seal spacers 80 while the LDD regions for p-type devices may be formed after forming the gate seal spacers 80.

In FIGS. 19A-19D, source/drain regions 82 are formed in the fins 52 to exert stress in the respective channel regions 58, thereby improving performance. The source/drain regions 82 are formed in the fins 52 such that each dummy gate 72 is disposed between respective neighboring pairs of the source/drain regions 82. In some embodiments the source/drain regions 82 may extend into, and may also penetrate through, the fins 52. In some embodiments, the gate spacers 86 are used to separate the source/drain regions 82 from the dummy gates 72 by an appropriate lateral distance so that the source/drain regions 82 do not short out subsequently formed gates of the resulting FinFETs.

The formation of the source/drain regions 82 may be formed by distinct processes, such that the source/drain regions 82 may be different materials in each region and may be formed by distinct processes. Various masking steps may be used to mask and expose appropriate regions when using distinct processes.

Referring first to FIGS. 18A and 18B, a patterning process is performed on the fins 52 to form recesses 85 in source/drain regions of the fins 52. The patterning process may be performed in a manner that the recesses 85 are formed between neighboring dummy gate stacks 72/74 (in interior regions of the fins 52), or between an isolation region 56 and adjacent dummy gate stacks 72/74 (in end regions of the fins 52). In some embodiments, the patterning process may include a suitable anisotropic dry etching process, while using the dummy gate stacks 72/74, the gate spacers 86, and/or isolation regions 56 as a combined mask. The suitable anisotropic dry etching process may include a reactive ion etch (RIE), neutral beam etch (NBE), the like, or a combination thereof. In some embodiments where the RIE is used in the first patterning process, process parameters such as, for example, a process gas mixture, a voltage bias, and an radio frequency (RF) power may be chosen such that etching is predominantly performed using physical etching, such as ion bombardment, rather than chemical etching, such as radical etching through chemical reactions. In some embodiments, a voltage bias may be increased to increase energy of ions used in the ion bombardment process and, thus, increase a rate of physical etching. Since the physical etching is anisotropic in nature and the chemical etching is isotropic in nature, such an etching process has an etch rate in the vertical direction that is greater than an etch rate in the lateral direction.

In FIGS. 19A-19D, an epitaxial layer 82B of the source/drain regions 82 is grown in the recesses 85. In the region 50N, e.g., the NMOS region, the epitaxial layer 82B may include any acceptable material, such as appropriate for n-type FinFETs. For example, if the fin 52 is silicon, the epitaxial layer 82B in the region 50N may include materials exerting a tensile strain in the channel region 58, such as silicon, silicon carbide, phosphorous doped silicon carbide, silicon phosphide, or the like. The epitaxial layer 82B in the region 50N may have surfaces raised from respective surfaces of the fins 52 and may have facets. In some embodiments, the epitaxial layers 82A and 82B are epitaxially grown in a single continuous process where the gas flows of the various precursors are changed to form the different layers. In some embodiments, the epitaxial layers 82A and 82B are formed in separate, distinct epitaxial growth processes.

In the region 50P, e.g., the PMOS region, the epitaxial layer 82B may include any acceptable material, such as appropriate for p-type FinFETs. For example, if the fin 52 is silicon, the epitaxial layer 82B in the region 50P may comprise materials exerting a compressive strain in the channel region 58, such as silicon-germanium, boron doped silicon-germanium, germanium, germanium tin, or the like. The epitaxial layer 82B in the region 50P may also have surfaces raised from respective surfaces of the fins 52 and may have facets.

As a result of the epitaxy processes used to form the source/drain regions 82 in the region 50N and the region 50P, upper surfaces of the source/drain regions 82 have facets which expand laterally outward beyond sidewalls of the fins 52. In some embodiments, these facets cause adjacent epitaxial layers 82B of the source/drain regions 82 of a same FinFET to merge as illustrated by FIG. 19C. In other embodiments, adjacent epitaxial layers 82B of the source/drain regions 82 remain separated after the epitaxy process is completed as illustrated by FIG. 19D. In the embodiments illustrated in FIGS. 19C and 19D, gate spacers 86 are formed covering a portion of the sidewalls of the fins 52 that extend above the STI regions 56 thereby blocking the epitaxial growth. In some other embodiments, the spacer etch used to form the gate spacers 86 may be adjusted to remove the spacer material to allow the epitaxially grown region to extend to the surface of the STI region 56.

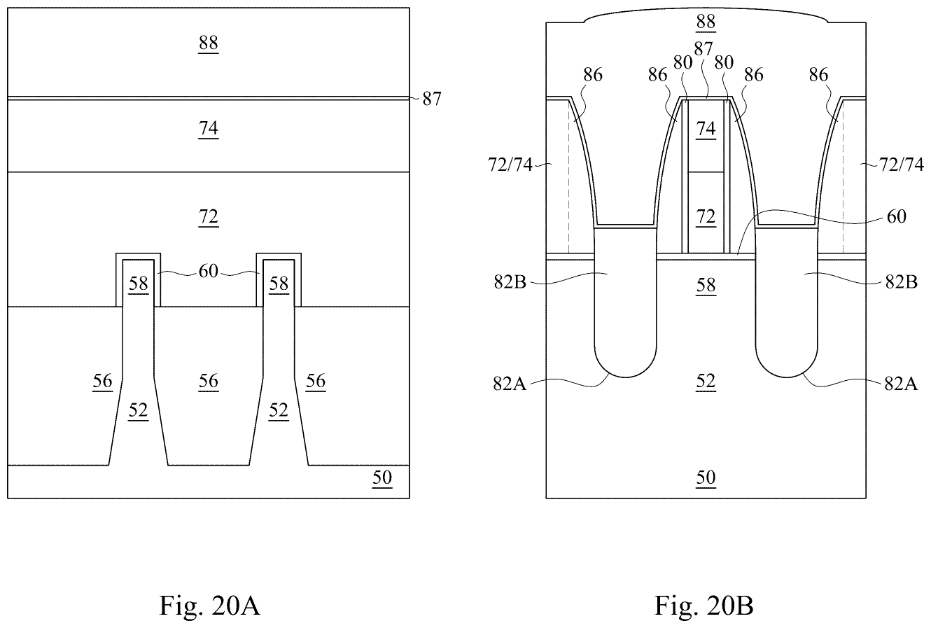

In FIGS. 20A and 20B, a first interlayer dielectric (ILD) 88 is deposited over the structure illustrated in FIGS. 19A and 19B. The first ILD 88 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 87 is disposed between the first ILD 88 and the epitaxial layer 82B of the source/drain regions 82, the masks 74, and the gate spacers 86. The CESL 87 may comprise a dielectric material, such as, silicon nitride, silicon oxide, silicon oxynitride, or the like, having a different etch rate than the material of the overlying first ILD 88.

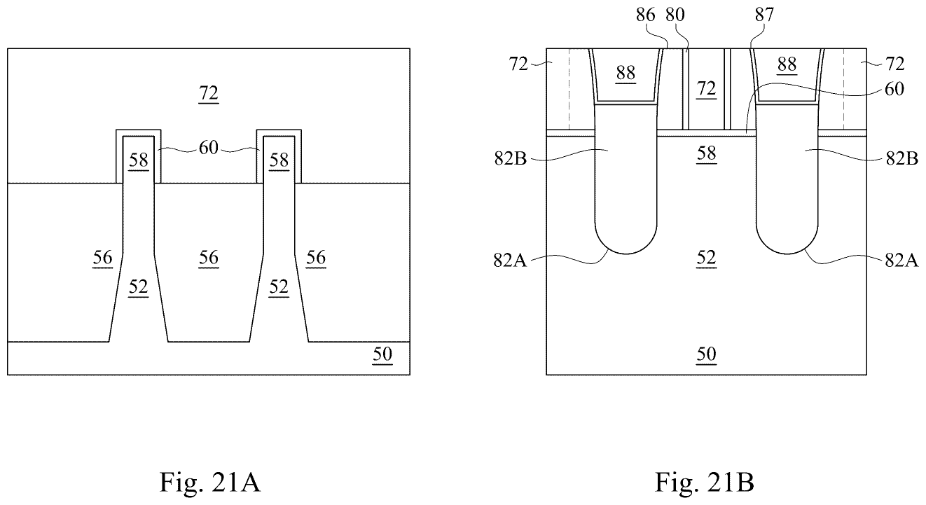

In FIGS. 21A and 21B, a planarization process, such as a CMP, may be performed to level the top surface of the first ILD 88 with the top surfaces of the dummy gates 72 or the masks 74. The planarization process may also remove the masks 74 on the dummy gates 72, and portions of the gate seal spacers 80 and the gate spacers 86 along sidewalls of the masks 74. After the planarization process, top surfaces of the dummy gates 72, the gate seal spacers 80, the gate spacers 86, and the first ILD 88 are level. Accordingly, the top surfaces of the dummy gates 72 are exposed through the first ILD 88. In some embodiments, the masks 74 may remain, in which case the planarization process levels the top surface of the first ILD 88 with the top surfaces of the top surface of the masks 74.

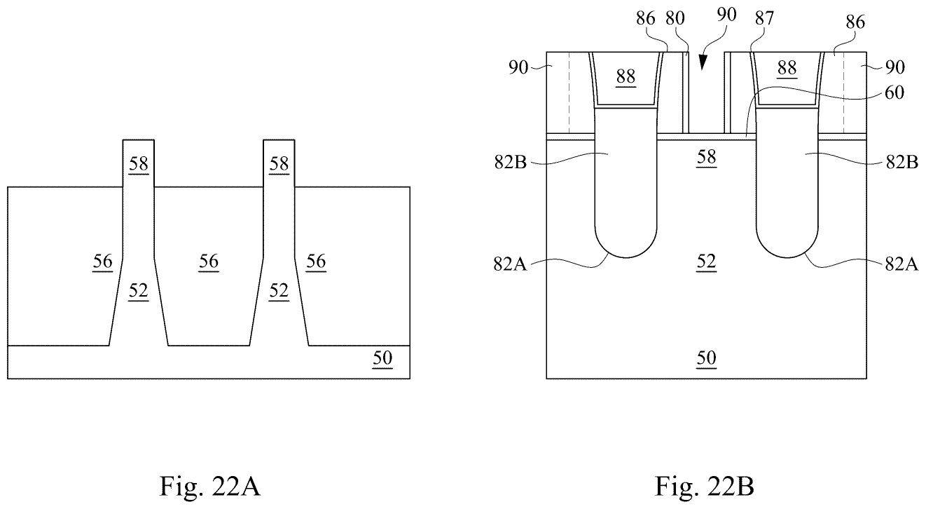

In FIGS. 22A and 22B, the dummy gates 72, and the masks 74 if present, are removed in an etching step(s), so that recesses 90 are formed. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process. For example, the etching process may include a dry etch process using reaction gas(es) that selectively etch the dummy gates 72 without etching the first ILD 88 or the gate spacers 86. Each recess 90 exposes and/or overlies a channel region 58 of a respective fin 52. Each channel region 58 is disposed between neighboring pairs of the source/drain regions 82. During the removal, the dummy dielectric layer 60 may be used as an etch stop layer when the dummy gates 72 are etched. The dummy dielectric layer 60 may then be optionally removed after the removal of the dummy gates 72.

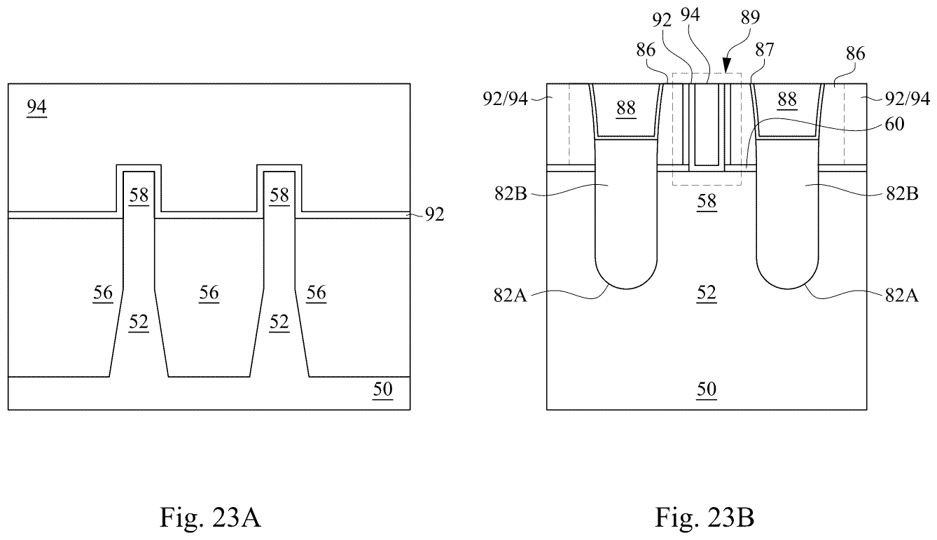

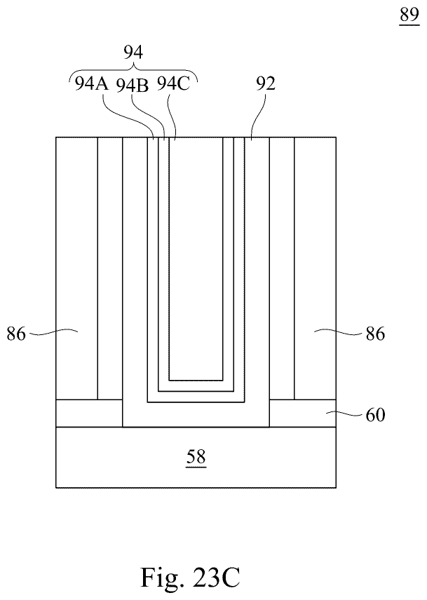

In FIGS. 23A and 23B, gate dielectric layers 92 and gate electrodes 94 are formed for replacement gates. FIG. 23C illustrates a detailed view of region 89 of FIG. 21B. Gate dielectric layers 92 are deposited conformally in the recesses 90, such as on the top surfaces and the sidewalls of the fins 52 and on sidewalls of the gate seal spacers 80/gate spacers 86. The gate dielectric layers 92 may also be formed on the top surface of the first ILD 88. In accordance with some embodiments, the gate dielectric layers 92 comprise silicon oxide, silicon nitride, or multilayers thereof. In some embodiments, the gate dielectric layers 92 include a high-k dielectric material, and in these embodiments, the gate dielectric layers 92 may have a k value greater than about 7.0, and may include a metal oxide or a silicate of hafnium, aluminum, zirconium, lanthanum, manganese, barium, titanium, lead, and combinations thereof. The formation methods of the gate dielectric layers 92 may include molecular-beam deposition (MBD), atomic layer deposition (ALD), PECVD, or the like. In embodiments where portions of the dummy dielectric layer 60 remains in the recesses 90, the gate dielectric layers 92 include a material of the dummy dielectric layer 60 (e.g., silicon oxide).

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode 94 is illustrated in FIG. 23B, the gate electrode 94 may comprise any number of liner layers 94A, any number of work function tuning layers 94B, and a fill material 94C as illustrated by FIG. 23C. After the filling of the recesses 90, a planarization process, such as a CMP, may be performed to remove the excess portions of the gate dielectric layers 92 and the material of the gate electrodes 94, which excess portions are over the top surface of the first ILD 88. The remaining portions of material of the gate electrodes 94 and the gate dielectric layers 92 thus form replacement gates of the resulting FinFETs. The gate electrodes 94 and the gate dielectric layers 92 may be collectively referred to as a “gate stack.” The gate and the gate stacks may extend along sidewalls of a channel region 58 of the fins 52.

The formation of the gate dielectric layers 92 in the region 50N and the region 50P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

Embodiments may achieve advantages. One advantage is that by using the photoresist composition formed by the first metallic photoresist and the second metallic photoresist, high EUV resolution patterns (such as about 13 nm to about 16 nm) can be obtained using low energy dose. Another advantage is that the metal content of the photoresist composition is high such that an etching rate of the photoresist layer can be increased.

In some embodiments, a photoresist composition comprises a first metallic photoresist and a second metallic photoresist. The first metallic photoresist has a formula (1):
(RSn)₁₂O₁₄(OH)₆](X)₂ (1), wherein in the formula (1), R is alkyl or alkenyl, and X is BF₄, OTf or SbF₆. The second metallic photoresist has a composition different from the formula (1) of the first metallic photoresist. In some embodiments, second metallic photoresist has formulae (2), (2′) or (2″):
(RSn)₆O₄C₁₂(R′CO₂)₈ (2); (RSn)₆₋ₓ(R′Sn)ₓO₄Cl₂(R″CO₂)₈ (2′)
(RSn)₆O₄Cl₂(R′CO₂)₈₋ₓ(R″CO₂)ₓ or (2″), wherein in the formulae (2), (2′) and (2″), and R, R′ and R″ are independently alkyl or alkenyl. In some embodiments, the second metallic photoresist has a formula (2a):
(vinylSn)₆O₄Cl₂(sec-butylCO₂)₈ (2a). In some embodiments, the second metallic photoresist has a formula (2b):
(vinylSn)₆O₄C₁₂(sec-C₄H₇CO₂)₈ (2b). In some embodiments, the second metallic photoresist has formulae (3) or (3′):
Hf₆O₄(OH)₈ (RCO₂)₈ (3); or Hf₆O₄(OH)₈(R′CO₂)₈₋ₓ(R″CO₂)ₓ (3′). In some embodiments, the second metallic photoresist has a formula (3a):
Hf₆O₄(OH)₈(sec-C₄H₇CO₂)₈ (3a). In some embodiments, the second metallic photoresist has formulae (4), (4′), (5) or (5′):
(RSn)₆O₄(OH)₁₀ (4); (RSn)ₓ(R′Sn)₆₋ₓO₄(OH)₁₀ (4′);
(RSn)₆O₄(RCO₂)ₓ(OH)₁₀₋ₓ (5); or
(RSn)₆(R′Sn)₆₋ₓO₄(R″CO₂)ₓ (OH)₁₀₋ₓ (5′), wherein in the formulae (4), (4′), (5) and (5′),
R, R′ or R″ are independently alkyl or alkenyl, x is 1.0 to 5.0. In some embodiments, the second metallic photoresist has a formula (5a):
Sn₆(C₃H₅)₁(C₄H₉)₅O₄(CH₃CO₂)₂(OH)₈ formula (5a). In some embodiments, the second metallic photoresist has a formula (5b):
Sn₆(C₃H₅)₆(CH₃COO)₆O₄(OH)₄ formula (5b).

In some embodiments, a lithography method comprises the following steps. A target layer is formed over a substrate. A photoresist composition is applied over the target layer to form a photoresist layer, wherein the photoresist composition comprises a first metallic photoresist and a second metallic photoresist, having a composition different from a composition of the first metallic photoresist, the first metallic photoresist comprises a Sn oxide cluster. The photoresist layer is exposed. The photoresist layer is developed. The target layer is etched using the photoresist layer as an etch mask. In some embodiments, the second metallic photoresist comprises Sn or Hf. In some embodiments, the first metallic photoresist comprises a formula (1):
[(RSn)₁₂O₁₄(OH)₆](X)₂ (1), wherein in the formula (1), R is alkyl or alkenyl, and X is BF₄, OTf or SbF₆. In some embodiments, the second metallic photoresist comprises a formula comprising a number of Sn atoms less than a number of Sn atoms of the formula (1). In some embodiments, the formula of the second metallic photoresist comprises carboxylate ligands. In some embodiments, the second metallic photoresist comprises a formula comprising a number of Hf atoms less than a number of Sn atoms of the formula (1). In some embodiments, the formula of the second metallic photoresist comprises carboxylate ligands.

In some embodiments, an extreme ultraviolet lithography (EUVL) method comprises the following steps. A droplet generator is turned on to eject a metal droplet toward a zone of excitation in front of a collector. A laser source is turned on to emit a laser toward the zone of excitation, such that the metal droplet is heated by the laser to generate EUV radiation. The EUV radiation is guided, by using one or more first optics, toward a reflective mask in an exposure device. The EUV radiation is guided, by using one or more second optics, reflected from the reflective mask toward a photoresist layer coated substrate in the exposure device. The photoresist layer is formed by applying a photoresist composition comprising a first metallic photoresist and a second metallic photoresist, the first metallic photoresist has a formula (1): [(RSn)₁₂O₁₄(OH)₆](X)₂ (1), wherein in the formula (1), R is alkyl or alkenyl, and X is BF₄, OTf or SbF₆, and the second metallic photoresist has a composition different from the formula (1). In some embodiments, the second metallic photoresist is an HfO₂-based photoresist. In some embodiments, the second metallic photoresist is a 6Sn-2Cl cluster. In some embodiments, the second metallic photoresist is a 6Sn-oxide cluster.

The foregoing outlines features of several embodiments or examples so that those skilled in the art may better understand the aspects of the present disclosure. Those skilled in the art should appreciate that they may readily use the prese0nt disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photoresist composition, comprising:
a first metallic photoresist having a formula (1):
[(RSn)₁₂O₁₄(OH)₆](X)₂ (1), wherein in the formula (1), R is alkyl or alkenyl, and X is BF₄, OTf or SbF₆; and
a second metallic photoresist having a composition different from the formula (1) of the first metallic photoresist.

2. The photoresist composition of claim 1, wherein second metallic photoresist has formulae (2), (2′) or (2″):
(RSn)₆O₄C₁₂(R′CO₂)₈ (2); (RSn)₆₋ₓ(R′Sn)ₓO₄C₁₂(R″CO₂)₈ (2′)
(RSn)₆O₄Cl₂(R′CO₂)₈₋ₓ(R″CO₂)ₓ or (2″), wherein in the formulae (2), (2′) and (2″), and R, R′ and R″ are independently alkyl or alkenyl.

3. The photoresist composition of claim 2, wherein the second metallic photoresist has a formula (2a):
(vinylSn)₆O₄Cl₂(sec-butylCO₂)₈ (2a).

4. The photoresist composition of claim 1, wherein the second metallic photoresist has a formula (2b):
(vinylSn)₆O₄Cl₂(sec-C₄H₇CO₂)₈ (2b).

5. The photoresist composition of claim 1, wherein the second metallic photoresist has formulae (3) or (3′):
Hf₆O₄(OH)₈ (RCO₂)₈ (3); or Hf₆O₄(OH)₈ (R′CO₂)₈₋ₓ(R″CO₂)ₓ (3′).

6. The photoresist composition of claim 1, wherein the second metallic photoresist has a formula (3a):
Hf₆O₄(OH)₈ (sec-C₄H₇CO₂)₈ (3a).

7. The photoresist composition of claim 1, wherein the second metallic photoresist has formulae (4), (4′), (5) or (5′):
(RSn)₆O₄(OH)₁₀ (4); (RSn)ₓ(R′Sn)₆₋ₓO₄(OH)₁₀ (4′);
(RSn)₆O₄(RCO₂)ₓ(OH)₁₀₋ₓ (5); or
(RSn)₆(R′Sn)₆₋ₓO₄(R″CO₂)ₓ (OH)₁₀₋ₓ (5′), wherein in the formulae (4), (4′), (5) and (5′), R, R′ or R″ are independently alkyl or alkenyl, x is 1.0 to 5.0.

8. The photoresist composition of claim 1, wherein the second metallic photoresist has a formula (5a):
Sn₆(C₃H₅)₁(C₄H₉)₅O₄(CH₃CO₂)₂(OH)₈ formula (5a).

9. The photoresist composition of claim 1, wherein the second metallic photoresist has a formula (5b):
Sn₆(C₃H₅)₆(CH₃COO)₆O₄(OH)₄ formula (5b).

10. A lithography method, comprising:
forming a target layer over a substrate;
applying a photoresist composition over the target layer to form a photoresist layer, wherein the photoresist composition comprises a first metallic photoresist and a second metallic photoresist, having a composition different from a composition of the first metallic photoresist, the first metallic photoresist comprises a Sn oxide cluster;
exposing the photoresist layer;
developing the photoresist layer; and
etching the target layer using the photoresist layer as an etch mask.

11. The lithography method of claim 10, wherein the second metallic photoresist comprises Sn or Hf.

12. The lithography method of claim 11, wherein the first metallic photoresist comprises a formula (1):
[(RSn)₁₂O₁₄(OH)₆](X)₂ (1), wherein in the formula (1), R is alkyl or alkenyl, and X is BF₄, OTf or SbF₆.

13. The lithography method of claim 12, wherein the second metallic photoresist comprises a formula comprising a number of Sn atoms less than a number of Sn atoms of the formula (1).

14. The lithography method of claim 13, wherein the formula of the second metallic photoresist comprises carboxylate ligands.

15. The lithography method of claim 12, wherein the second metallic photoresist comprises a formula comprising a number of Hf atoms less than a number of Sn atoms of the formula (1).

16. The lithography method of claim 15, wherein the formula of the second metallic photoresist comprises carboxylate ligands.

17. An extreme ultraviolet lithography (EUVL) method, comprising:
turning on a droplet generator to eject a metal droplet toward a zone of excitation in front of a collector;
turning on a laser source to emit a laser toward the zone of excitation, such that the metal droplet is heated by the laser to generate EUV radiation;
guiding the EUV radiation, by using one or more first optics, toward a reflective mask in an exposure device; and
guiding the EUV radiation, by using one or more second optics, reflected from the reflective mask toward a photoresist layer coated substrate in the exposure device,
wherein the photoresist layer is formed by applying a photoresist composition comprising a first metallic photoresist and a second metallic photoresist, the first metallic photoresist has a formula (1):
[(RSn)₁₂O₁₄(OH)₆](X)₂ (1), wherein in the formula (1), R is alkyl or alkenyl, and X is BF₄, OTf or SbF₆, and the second metallic photoresist has a composition different from the formula (1).

18. The EUVL method of claim 17, wherein the second metallic photoresist is an HfO₂-based photoresist.

19. The EUVL method of claim 17, wherein the second metallic photoresist is a 6Sn-2Cl cluster.

20. The EUVL method of claim 17, wherein the second metallic photoresist is a 6Sn—oxide cluster.
